(19) United States
(12) Patent Application Publication
(10) Pub. No.: US 2011/0244398 A1
(43) Pub. Date: Oct. 6, 2011

(54) Patterning method

(75) Inventors: Wei-Hang Huang, Kaohsiung County (TW); Jiunn-Hsiung Liao, Tainan County (TW); Pei-Yu Chou, Tainan County (TW)

(73) Assignee: United Microelectronics Corp, Hsinchu (TW)

(21) Appl. No.: 12/798,207

(22) Filed: Mar. 30, 2010

(51) Int. Cl. G03F 7/20

(52) U.S. Cl. 430/323

(57) ABSTRACT

A patterning method is provided. First, a first mask layer, a second mask layer and a patterned photoresist layer are sequentially formed on a target layer. Thereafter, the second mask layer is etched by using the patterned photoresist layer as a mask, so as to form a patterned second mask layer. Afterwards, a trimming process is performed to the patterned second mask layer. Further, the first mask layer is etched by using the trimmed patterned second mask layer as a mask, so as to form a patterned first mask layer. The patterned photoresist layer is then removed. Next, the target layer is etched by using the patterned first mask layer as a mask.

### BACKGROUND OF THE INVENTION

1. Field of Invention

The present invention relates to a semiconductor process, and more particularly to a patterning method.

2. Description of Related Art

As the level of integration of a semiconductor device is getting higher, the critical dimension of the same is getting smaller. Minimizing the critical dimension and increasing the level of integration have become the mainstream in the industry, and the key technology is in photolithography and etching.

In a photolithography process, it is known that raising a line or space resolution beyond 40 nm in the current state of semiconductor technology is rather difficult, unless a light source having a shorter wavelength and a corresponding photoresist are used. However, it is very costly to replace existing equipment entirely with new machines for this purpose. Therefore, how to use an etching process to meet the purpose of minimizing the critical dimension has been one of the main topics in the industry.

In the process of forming a gate, one known method includes sequentially forming a polysilicon layer, a SiN mask layer and a patterned photoresist layer on a substrate. Thereafter, the SiN mask layer is etched by using the patterned photoresist layer as a mask, so as to form a patterned SiN mask layer. Afterwards, a trimming process is performed to the patterned SiN mask layer. Further, the polysilicon layer is etched by using the trimmed patterned SiN mask layer, so as to form the gate.

In one case, a thinner SiN mask layer is used, and the purpose of trimming the line width of the patterned SiN mask layer is easily met. However, during the step of forming the patterned SiN mask layer, the patterned photoresist layer is subjected to the lateral etching more than the thickness reduction thereof, so that a high aspect ratio of the patterned photoresist layer is caused and photoresist collapse occurs.

In another case, a thicker SiN mask layer is used. During the step of forming the patterned SiN mask layer, the patterned photoresist layer is subjected to the thickness reduction more than the lateral etching thereof, so that photoresist collapse is not observed. However, the purpose of trimming the line width of the patterned SiN mask layer is difficultly met due to the larger thickness of the SiN mask layer.

The process window of the above-mentioned patterning method is narrow. Even though the critical dimension is reduced to below 40 nm by the above-mentioned patterning method, the formed patterns are distorted, as referred to scanning electron microscope (SEM) pictures of testing patterns A-F in FIG. 1. There exist a difference between the line width measured by SEM and the real line width obtained by transmission electron microscope (TEM). The real line width obtained by TEM is smaller than the line with measured by SEM by about 12-13 nm.

### SUMMARY OF THE INVENTION

Accordingly, the present invention provides a patterning method, in which photoresist collapse does not occur to form distorted patterns during the etching process, the critical dimension can be reduced easily and the process window is wide enough.

The present invention provides a patterning method. First, a first mask layer, a second mask layer and a patterned photoresist layer are sequentially formed on a target layer. Thereafter, the second mask layer is etched by using the patterned photoresist layer as a mask, so as to form a patterned second mask layer. Afterwards, a trimming process is performed to the patterned second mask layer. Further, the first mask layer is etched by using the trimmed patterned second mask layer as a mask, so as to form a patterned first mask layer. The patterned photoresist layer is then removed. Next, the target layer is etched by using the patterned first mask layer as a mask.

According to an embodiment of the present invention, the target layer includes polysilicon, for example.

According to an embodiment of the present invention, the first mask layer and the second mask layer include different materials.

According to an embodiment of the present invention, the first mask layer includes silicon nitride, and the second mask layer includes silicon oxide, for example.

According to an embodiment of the present invention, the first mask layer includes silicon oxide, and the second mask layer includes silicon nitride, for example.

According to an embodiment of the present invention, the patterned photoresist layer has multiple layers. For example, the patterned photoresist layer includes, from bottom to top, a 365 nm photoresist layer, a Si-containing hard-mask bottom anti-reflection coating (SHB) layer and a 193 nm photoresist layer.

According to an embodiment of the present invention, the step of forming the patterned first mask layer and the step of forming the patterned second mask layer each include performing a dry etching process, in which the reaction gases include CF₄, HBr, CHF₃, He or a combination thereof.

According to an embodiment of the present invention, the step of forming the patterned second mask layer includes using HBr gas, so as to prevent the patterned photoresist layer from collapsing.

According to an embodiment of the present invention, the flow rate of HBr gas is about 100-150 sccm, for example.

According to an embodiment of the present invention, the time of the trimming process is about 40-60 seconds, for example.

The present invention further provides a patterning method. First, a first mask layer, a second mask layer and a patterned photoresist layer are sequentially formed on a target layer. Thereafter, the second mask layer and the first mask layer are sequentially etched by using the patterned photoresist layer as a mask, so as to form a patterned second mask layer and a patterned first mask layer. Afterwards, a trimming process is performed to the patterned second mask layer and the patterned first mask layer. The patterned photoresist layer is then removed. Next, the target layer is etched by using the trimmed patterned first mask layer as a mask.

According to an embodiment of the present invention, the target layer includes polysilicon, for example.

According to an embodiment of the present invention, the first mask layer and the second mask layer include different materials.

According to an embodiment of the present invention, the first mask layer includes silicon nitride, and the second mask layer includes silicon oxide, for example.

According to an embodiment of the present invention, the first mask layer includes silicon oxide, and the second mask layer includes silicon nitride, for example.

According to an embodiment of the present invention, the patterned photoresist layer has multiple layers. For example, the patterned photoresist layer includes, from bottom to top, a 365 nm photoresist layer, a SHB layer and a 193 nm photoresist layer.

According to an embodiment of the present invention, the step of forming the patterned second mask layer and the patterned first mask layer does not include using HBr gas.

According to an embodiment of the present invention, the time of trimming process is about 50-70 seconds, for example.

In view of above, the patterning method of the present invention can reduce the critical dimension with the existing equipment by using a trimming process and a stacked structure including dual mask layers. Further, the patterning method of the present invention is very competitive due to the simple process and wide process window thereof.

In order to make the aforementioned and other objects, features and advantages of the present invention comprehensible, a preferred embodiment accompanied with figures is described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 shows scanning electron microscope (SEM) pictures of testing patterns A-F formed by the conventional patterning method.

FIGS. 2A to 2E schematically illustrate cross-sectional views of a patterning method according to a first embodiment of the present invention.

FIG. 3A to 3B schematically illustrates top views of a patterning method according to the first embodiment of the present invention.

FIG. 4 shows SEM pictures of testing patterns A-F formed by Example 1 to Example 3 of the present invention.

FIGS. 5A to 5D schematically illustrate cross-sectional views of a patterning method according to a second embodiment of the present invention.

FIG. 6 shows SEM pictures of testing patterns A-F formed by Example 4 to Example 7 of the present invention.

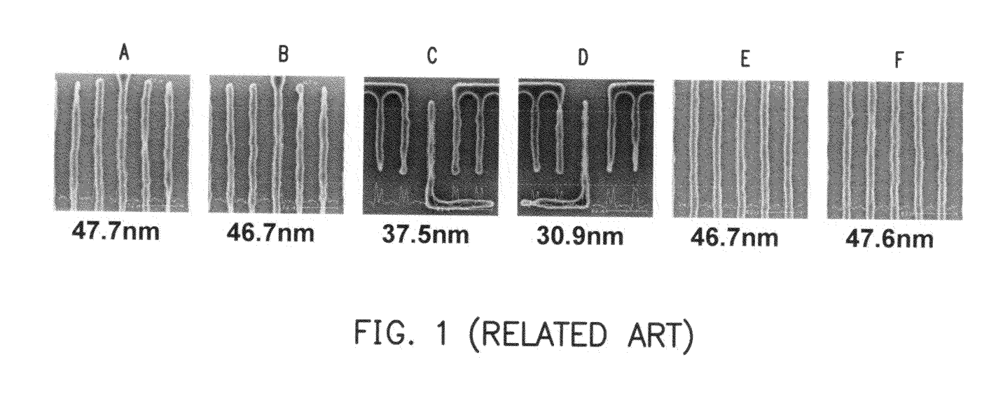

### DESCRIPTION OF EMBODIMENTS

### First Embodiment

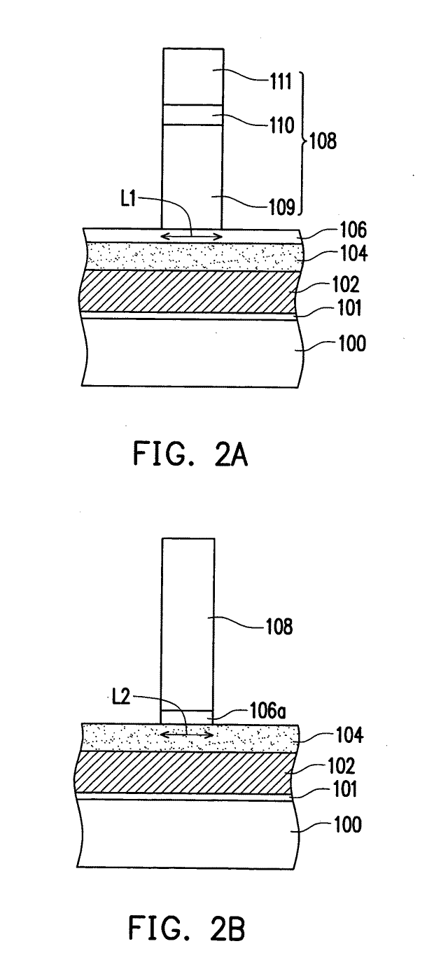

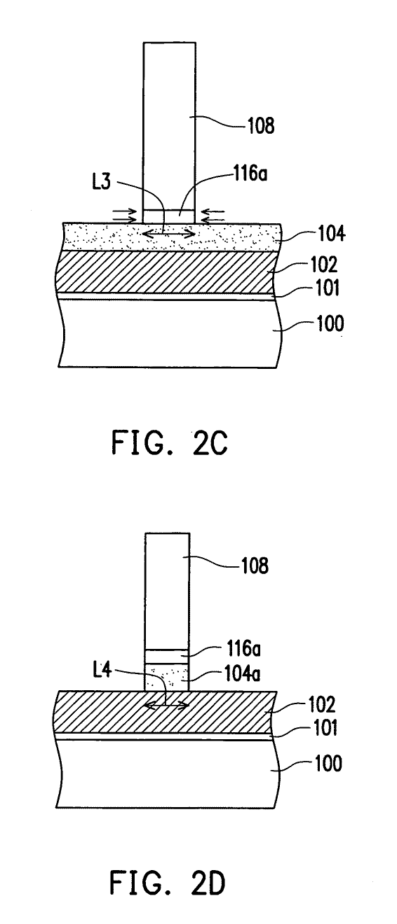

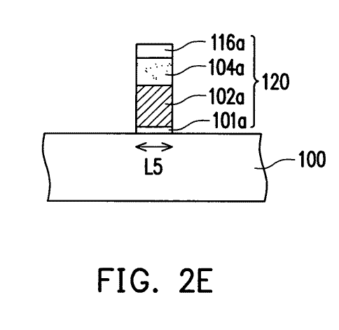

FIGS. 2A to 2E schematically illustrate cross-sectional views of a patterning method according to a first embodiment of the present invention.

Referring to FIG. 2A, a target layer 102, a first mask layer 104, a second mask layer 106 and a patterned photoresist layer 108 are sequentially formed on a substrate 100. The substrate 100 may be a silicon substrate. The target layer 102 is a polysilicon layer of 800 Å, and the forming method thereof includes performing a chemical vapor deposition (CVD) process, for example. In an embodiment, a dielectric layer 101 is optionally formed between the substrate 100 and the target layer 102. The dielectric layer 101 is a silicon oxide layer, and the forming method thereof includes performing a thermal oxide process, for example. The first mask layer 104 is a silicon nitride layer of 450 Å, for example. The second mask layer 106 is a silicon oxide layer of 200 Å, for example. The method of forming the first mask layer 104 and the second mask layer 106 includes performing a CVD process, for example.

The patterned photoresist layer 108 includes, from bottom to top, a 365 nm photoresist layer 109 (reactive to 365 nm wavelength light) of 1500 Å, a Si-containing hard-mask bottom anti-reflection coating (SHB) layer 110 of 300 Å and a 193 nm photoresist layer (reactive to 193 nm wavelength light) 111 of 800 Å. Further, the line width of the patterned photoresist layer is L1.

Referring to FIG. 2B, the second mask layer 106 is etched by using the patterned photoresist layer 108 as a mask, so as to form a patterned second mask layer 106a. The method of forming the patterned second mask layer 106a includes performing a dry etching process, in which the reaction gases include CF₄, HBr, CHF₃, He or a combination thereof, for example. During the step of etching the second mask layer 106, the patterned photoresist layer 108 is subjected to both lateral etching and thickness reduction thereof, so that the aspect ratio of the patterned photoresist layer 108 is changed. Accordingly, in the present invention, a large amount of HBr gas having the function of protecting the patterned photoresist layer 108 is added, and the flow rate of HBr gas maintains about 100-150 sccm. Therefore, photoresist collapse due to the high aspect ratio of the patterned photoresist layer 108 during the step of etching the second mask layer 106 is not observed. In addition, the line width of the patterned second mask layer 106a is reduced from L1 to L2 due to the lateral etching.

Referring to FIG. 2C, a trimming process is performed to the patterned second mask layer 106a, so as to form a trimmed patterned second mask layer 116a. The line width of the trimmed patterned second mask layer 116a is reduced from L2 to L3. During the trimming process, the thickness of the patterned second mask layer 106a is small enough (about 200 Å), so that the purpose of trimming the line width of the patterned second mask layer 106a is easily achieved. Further, the trimming process is a dry etching process, in which the reaction gases include CF₄ and CHF₃, and the time is about 40-60 seconds, for example.

Referring to FIG. 2D, the first mask layer 104 is etched by using the trimmed patterned second mask layer 116a as a mask, so as to form a patterned first mask layer 104a. The method of forming the patterned first mask layer 104a includes performing a dry etching process, in which the reaction gases include CF₄, HBr, CHF₃, He or a combination thereof, for example. In addition, the line width of the patterned first mask layer 104a is reduced from L3 to L4 due to the lateral etching.

Referring to FIG. 2E, the patterned photoresist layer 108 is removed. Thereafter, the target layer 102 and the dielectric layer 101 are sequentially etched by using the patterned first mask layer 104a as a mask, so as to form a patterned target layer 102a and a patterned dielectric layer 101a. The method of forming the patterned target layer 102a includes performing a breakthrough etching step, a main etching step, an extension etching step and an over etching step. The reaction gases of the breakthrough etching step include CF₄, NF₃ and SF₆. The reaction gases of the main etching step and the extension etching step include HBr and HeO₂. The reaction gases of the over etching step include HBr, HeO₂ and He. The line width of the patterned target layer 102a is reduced from L4 to L5 due to the lateral etching. Further, the trimmed patterned second mask layer 116a, the patterned first mask layer 104a, the patterned target layer 102a and the patterned dielectric layer 101a form a stacked structure 120.

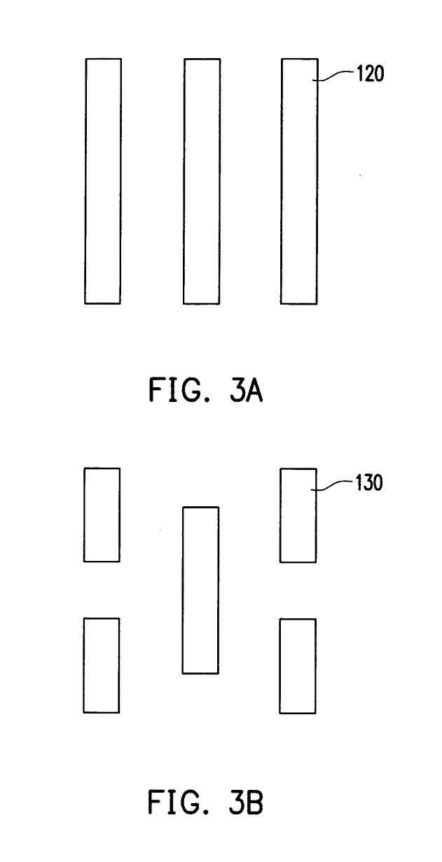

It is noted that a plurality of the stacked structures 120 is substantially arranged in strips, as shown in the top view of FIG. 3A. Another patterning process can be performed to the strip-shaped stacked structures 120, so as to form block-shaped stacked structures 130, as shown in FIG. 3B. The method of forming the block-shaped stacked structures 130 includes performing a patterned photoresist layer having a plurality of openings (not shown) on the strip-shaped stacked structures 120. Thereafter, the strip-shaped stacked structures 120 are etched by using the patterned photoresist layer having the openings as a mask, so as to form the block-shaped stacked structures 130.

Further, the trimmed patterned second mask layer 116a is removed, so that the patterned first mask layer 104a remaining on the patterned target layer 102a is beneficial for the following processes, such as a self-aligned suicide (salicide) process.

The above-mentioned embodiment in which the first mask layer is a SiN mask layer and the second mask layer is a SiO mask layer is provided for illustration purposes, and is not construed as limiting the present invention. It is appreciated by persons skilled in the art that the materials of the first and second mask layers can be determined by the material to be left on the patterned target layer. For example, if the following process requires to form a SiO mask layer on the patterned target layer, the SiO mask layer can be used as the first mask layer, and the SiN mask layer can be used as the second mask layer.

As described above, according to the patterning method of the present invention, a stacked structure including dual mask layers replaces the conventional single mask layer. A large amount of HBr gas is used during the step of patterning the second mask layer (i.e. upper mask layer), so that distorted patterns of the patterned second mask layer caused by photoresist collapse of the patterned photoresist layer do not occur, and thus, patterns of the patterned first mask layer and patterns of the patterned target layer which are sequentially formed are not distorted. Further, the trimming process is performed to the second mask layer with smaller thickness, so that the purpose of trimming the line width of the patterned second mask layer is easily met. In addition, the material of the first mask layer (i.e. lower mask layer) remaining on the patterned target layer can be chosen upon the process requirement, so as to benefit the following processes such as a salicide process.

Several examples are numerated to prove the performance of the patterning method according to the first embodiment of the present invention.

### Example 1

First, a polysilicon layer of 600 Å, a SiN mask layer of 450 Å, a SiO mask layer of 200 Å and a patterned photoresist layer are sequentially formed on a substrate. The patterned photoresist layer includes, from bottom to top, a 365 nm photoresist layer of 1500 Å, a SHB layer of 300 Å and a 193 nm photoresist layer of 800 Å. Thereafter, the SiO mask layer is etched by using the patterned photoresist layer as a mask, so as to form a patterned SiO mask layer. Thereafter, a trimming process is performed to the patterned SiO mask layer. Further, the SiN mask layer is etched by using the trimmed patterned SiO mask layer as a mask, so as to form a patterned SiN mask layer. The patterned photoresist layer is then removed. Next, the polysilicon layer is etched by using the patterned SiN mask layer as a mask.

Table 1 shows pressure, transfer coupling plasma (TCP) power, bias power (BP), gas species and flow rates thereof and time for each etching step.

TABLE 1

| | | TCP | | | |
|---|---|---|---|---|---|
| | Pressure | power | BP | Flow rate (sccm)/ | Time |
| Step | (torr) | (watt) | (V) | Gas | (sec) |
| Etching SiO | 10 | 700 | 100 | 90/CF₄, | End |
| mask layer | | | | 15/CHF₃ , 270/He | point |
| Trimming process | 5 | 600 | 0 | 80/CF₄, 15/CHF₃ | 50″ |
| Etching SiN | 10 | 700 | 175 | 90/CF₄, 30/HBr, | End |
| mask layer | | | | 15/CHF₃, 270/He | point |
| Remove photoresist | 20 | 1000 | 0 | 6/CF₄, 200/O₂ | 60″ |
| layer | | | | | |
| Breakthrough | 2.5 | 500 | 110 | 60/CF₄, 10/NF₃ , | 10″ |
| etching of | | | | 7/SF₆ | |
| polysilicon layer | | | | | |
| Main etching of | 3 | 450 | 60 | 200/HBr, 20/ | End |
| polysilicon layer | | | | HeO₂ | point |
| Extension etching of | 3 | 450 | 30 | 200/HBr, 20/ | 3″ |
| polysilicon layer | | | | HeO₂ | |
| Over etching of | 60 | 450 | 175 | 180/HBr, | 40″ |
| polysilicon layer | | | | 10/HeO₂, 180/He | |

### Example 2

The materials and thicknesses of the layers and the etching methods are the same in Examples 2 and 1, except that additional 30 sccm of HBr gas is used during the step of etching the SiO mask layer. Table 2 only lists the step of etching the SiO mask layer, and other same steps are not iterated herein.

TABLE 2

| | | TCP | | | |
|---|---|---|---|---|---|
| | Pressure | power | BP | Flow rate (sccm)/ | Time |
| Step | (torr) | (watt) | (V) | Gas | (sec) |
| Etching SiO | 10 | 700 | 100 | 90/CF₄, 30/HBr, | End |
| mask layer | | | | 15/CHF₃, 270/He | point |

### Example 3

The materials and thicknesses of the layers and the etching methods are the same in Examples 3 and 1, except that additional 100 sccm of HBr gas is used during the step of etching the SiO mask layer. Table 3 only lists the step of etching the SiO mask layer, and other same steps are not iterated herein.

TABLE 3

| | Pressure | TCP | BP | Flow rate (sccm)/ | Time |
|---|---|---|---|---|---|
| Step | (torr) | (watt) | (V) | Gas | (sec) |
| Etching SiO | 10 | 700 | 100 | 90/CF₄, 100/HBr, | End point |
| mask layer | | | | 15/CHF₃, 270/He | |

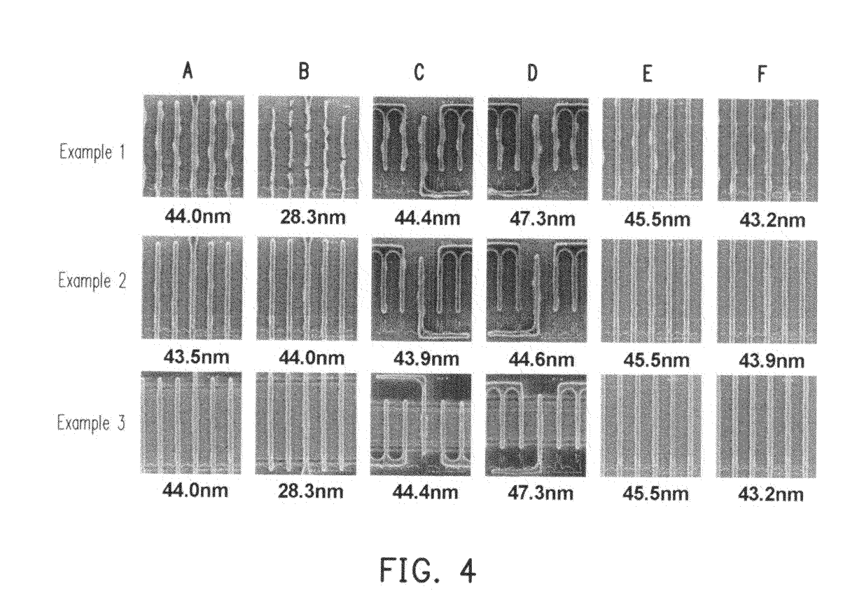

FIG. 4 shows SEM pictures of test patterns A-F formed by Example 1 to Example 3 of the present invention. In Example 1, no HBr gas is added to the step of etching the SiO mask layer, so that the patterns of the resulting stacked structure are distorted due to photoresist collapse. In Example 2 and Example 3, HBr gas is added during the step of etching the SiO mask layer to improve the profile of the resulting stacked structure, so that distorted patterns are not observed. As more HBr gas is added, a better profile of the resulting stacked structure is obtained.

### Second Embodiment

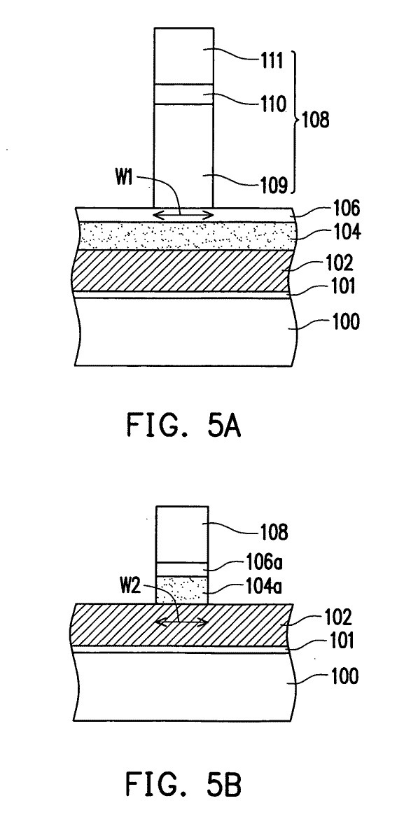

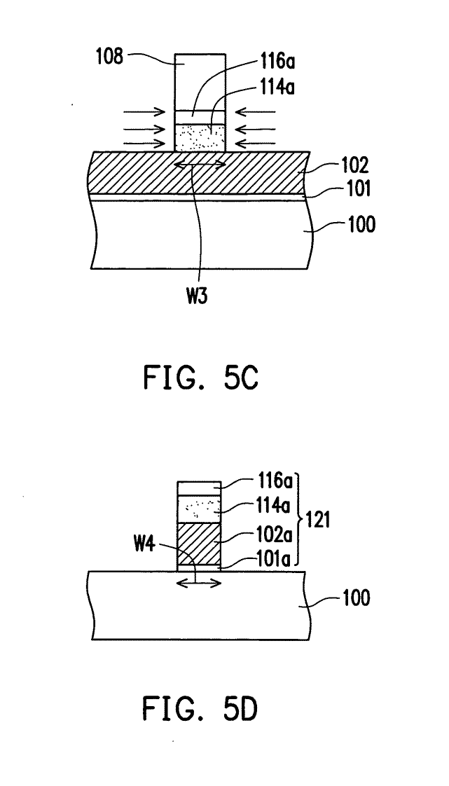

FIGS. 5A to 5D schematically illustrate cross-sectional views of a patterning method according to a second embodiment of the present invention.

Referring to FIG. 5A, a dielectric layer 101, a target layer 102, a first mask layer 104, a second mask layer 106 and a patterned photoresist layer 108 are sequentially formed on a substrate 100. The substrate 100 may be a silicon substrate. The dielectric layer 101 may be a silicon oxide layer. The target layer 102 is a polysilicon layer of 800 Å, for example. The first mask layer 104 is a silicon nitride layer of 450 Å, for example. The second mask layer 106 is a silicon oxide layer of 200 Å, for example. The dielectric layer 101, the target layer 102, the first mask layer 104 and the second mask layer 106 are formed by the same methods as described in the first embodiment, so that the details are not iterated. The patterned photoresist layer 108 includes, from bottom to top, a 365 nm photoresist layer 109 of 1500 Å, a SHB layer 110 of 300 Å and a 193 nm photoresist layer 111 of 800 Å. Further, the line width of the patterned photoresist layer is W1.

Referring to FIG. 5B, the second mask layer 106 and the first mask layer 104 are sequentially etched by using the patterned photoresist layer 108 as a mask, so as to form a patterned second mask layer 106a and a patterned first mask layer 104a. The method of forming the patterned second mask layer 106a and the patterned first mask layer 104a includes performing a dry etching process, in which the reaction gases include CF₄, CHF₃ and He, for example. It is noted that the step of forming the patterned second mask layer 106a and the patterned first mask layer 104a does not include using HBr gas having the function of protecting the patterned photoresist layer 108. The second mask layer 106 and the first mask layer 104 are thick enough (about 650 Å), and no HBr gas is used during the etching process, so that the patterned photoresist layer 108 is much thinned out without photoresist collapse. Further, the line width of the patterned second mask layer 106a and the patterned first mask layer 104a is reduced from W1 to W2 due to the lateral etching.

Referring to FIG. 5C, a trimming process is performed to the patterned second mask layer 106a and the patterned first mask layer 104a, so as to form a trimmed patterned second mask layer 116a and a trimmed patterned first mask layer 114a. The line width of the trimmed patterned second mask layer 116a and the trimmed patterned first mask layer 114a is reduced from W2 to W3. During the trimming process, the patterned second mask layer 106a and the patterned first mask layer 104a include different materials, so that polymer accumulated on the sidewall thereof is less than that accumulated on the sidewall of the single SiN mask layer of the same thickness (about 650 Å), and thus, the purpose of trimming the line width of the patterned second mask layer 106a and the patterned first mask layer 104a can be easily met. Further, the trimming process is a dry etching process, in which the reaction gases include CF₄ and CHF₃, and the time is about 50-70 seconds, for example.

Referring to FIG. 5D, the patterned photoresist layer 108 is removed. Thereafter, the target layer 102 and the dielectric layer 101 are sequentially etched by using the trimmed patterned first mask layer 114a as a mask, so as to form a patterned target layer 102a and a patterned dielectric layer 101a. The method of forming the patterned target layer 102a includes performing a breakthrough etching step, a main etching step, an extension etching step and an over etching step. The reaction gases of the breakthrough etching step include CF₄, NF₃ and SF₆. The reaction gases of the main etching step and the extension etching step include HBr and HeO₂. The reaction gases of the over etching step include HBr, HeO₂ and He. The line width of the patterned target layer 102a is reduced from W3 to W4 due to the lateral etching. Further, the trimmed patterned second mask layer 116a, the trimmed patterned first mask layer 114a, the patterned target layer 102a and the patterned dielectric layer 101a form a stacked structure 121.

In addition, another patterning process can be performed to the strip-shaped stacked structures 121, so as to form block-shaped stacked structures, as referred to FIGS. 3A and 3B of the first embodiment, and thus, the details are not iterated. Further, the trimmed patterned second mask layer 116a is removed, so that the trimmed patterned first mask layer 114a remaining on the patterned target layer 102a is beneficial for the following processes, such as a salicide process.

As described above, according to the patterning method of the present invention, a stacked structure including dual mask layers replaces the conventional single mask layer. No HBr gas is used during the step of patterning the second mask layer and the first mask layer, so that the patterned photoresist layer is much thinned out, and thus, distorted patterns caused by photoresist collapse do not occur. Accordingly, patterns of the patterned target layer which is sequentially formed are not distorted. Further, during the step of trimming the patterned second mask layer and the patterned first mask layer, the patterned second mask layer and the patterned first mask layer include different materials, so that polymer accumulated on the sidewall thereof is less than that accumulated on the sidewall of the single SiN mask layer of the same thickness, and thus, the purpose of trimming the line width of the patterned second mask layer and the patterned first mask layer can be easily met. In addition, the material of the first mask layer (i.e. lower mask layer) remaining on the patterned target layer can be chosen upon the process requirement, so as to benefit the following processes such as a salicide process.

Several examples are numerated to prove the performance of the patterning method according to the second embodiment of the present invention.

### Example 4

First, a polysilicon layer of 600 Å, a SiN mask layer of 450 Å, a SiO mask layer of 200 Å and a patterned photoresist layer are sequentially formed on a substrate. The patterned photoresist layer includes, from bottom to top, a 365 nm photoresist layer of 1500 Å, a SHB layer of 300 Å and a 193 nm photoresist layer of 800 Å. Thereafter, the SiO mask layer and the SiN mask layer are sequentially etched by using the patterned photoresist layer as a mask, so as to form a patterned SiO mask layer and a patterned SiN mask layer. Thereafter, a trimming process is performed to the patterned SiO mask layer and the patterned SiN mask layer. The patterned photoresist layer is then removed. Next, the polysilicon layer is etched by using the trimmed patterned SiN mask layer as a mask.

Table 4 shows pressure, transfer coupling plasma (TCP) power, bias power (BP), gas species and flow rates thereof and time for each etching step.

TABLE 4

| | Pressure | TCP | BP | Flow rate (sccm)/ | Time |
|---|---|---|---|---|---|
| Step | (torr) | (watt) | (V) | Gas | (sec) |
| Etching SiO mask | 10 | 700 | 100 | 90/CF₄, 30/HBr, | End |
| layer | | | | 15/CHF₃, 270/He | point |
| Etching SiN mask | 10 | 700 | 175 | 90/CF₄, 30/HBr, | End |
| layer | | | | 15/CHF₃, 270/He | point |
| Trimming process | 5 | 600 | 0 | 80/CF₄, 15/CHF₃ | 50″ |
| Remove photoresist | 20 | 1000 | 0 | 6/CF₄, 200/O₂ | 60″ |
| layer | | | | | |
| Breakthrough etching | 2.5 | 500 | 110 | 60/CF₄, 10/NF₃ , | 10″ |
| of polysilicon layer | | | | 7/SF₆ | |
| Main etching of | 3 | 450 | 60 | 200/HBr, 20/ | End |
| polysilicon layer | | | | HeO₂ | point |
| Extension etching of | 3 | 450 | 30 | 200/HBr, 20/ | 3″ |
| polysilicon layer | | | | HeO₂ | |
| Over etching of | 60 | 450 | 175 | 180/HBr, | 40″ |
| polysilicon layer | | | | 10/HeO₂, 180/He | |

### Example 5

The materials and thicknesses of the layers and the etching methods are the same in Examples 5 and 4, except that the trimming process is omitted.

### Example 6

The materials and thicknesses of the layers and the etching methods are the same in Examples 6 and 4, except that no HBr gas is used during the step of etching the SiO mask layer and the SiN mask layer. Table 5 only lists the step of etching the SiO mask layer and the SiN mask layer, and other same steps are not iterated herein.

TABLE 5

| | Pressure | TCP | BP | Flow rate (sccm)/ | Time |
|---|---|---|---|---|---|
| Step | (torr) | (watt) | (V) | Gas | (sec) |
| Etching SiO | 10 | 700 | 100 | 90/CF₄, 15/CHF₃ , | End point |
| mask layer | | | | 270/He | |
| Etching SiN | 10 | 700 | 175 | 90/CF₄, 15/CHF₃ , | End point |
| mask layer | | | | 270/He | |

### Example 7

The materials and thicknesses of the layers and the etching methods are the same in Examples 7 and 4, except that no HBr gas is used during the step of etching the SiO mask layer and the SiN mask layer and the time of the trimming process is 60 seconds instead of 50 seconds in Example 4. Table 6 only lists the step of etching the SiO mask layer and the SiN mask layer and the step of the trimming process, and other same steps are not iterated herein.

TABLE 6

| | Pressure | TCP | BP | Flow rate (sccm)/ | Time |
|---|---|---|---|---|---|
| Step | (torr) | (watt) | (V) | Gas | (sec) |
| Etching SiO | 10 | 700 | 100 | 90/CF₄, 15/CHF₃ , | End |
| mask layer | | | | 270/He | point |
| Etching SiN | 10 | 700 | 175 | 90/CF₄, 15/CHF₃ , | End |
| mask layer | | | | 270/He | point |
| Trimming process | 5 | 600 | 0 | 80/CF₄, 15/CHF₃ , | 60″ |

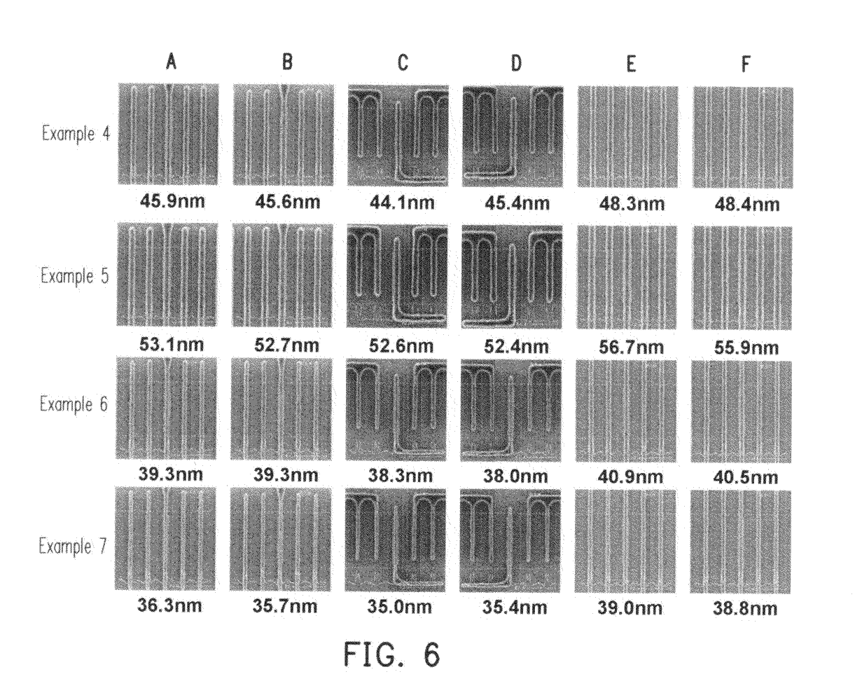

FIG. 6 shows SEM pictures of test patterns A-F formed by Example 4 to Example 7 of the present invention. The comparison between Example 4 and Example 5 proves that the trimming process helps to reduce the line width. The comparison between Example 4 and Example 6 shows that disuse of HBr gas not only avoids distorted patterns caused by photoresist collapse but also further reduces the line width of the resulting stacked structure. The comparison between Example 6 and Example 7 shows that the line width of the resulting stacked structure is reduce as the time of the trimming process is longer.

In summary, the patterning method of the present invention uses a trimming process and a stacked structure including dual mask layers, so that photoresist collapse does not occur to form distorted patterns during the etching process, and the critical dimension can be reduced easily. Further, the patterning method in accordance with the present invention can be done in a single etching chamber. The process is simple and the process window thereof is wide enough. In addition, the patterning method of the present invention can effectively reduce the critical dimension without replacing any existing manufacturing equipment in the fabrication. Thus, the process cost is greatly saved, and the competitive advantage is achieved.

This invention has been disclosed above in the preferred embodiments, but is not limited to those. It is known to persons skilled in the art that some modifications and innovations may be made without departing from the spirit and scope of this invention. Hence, the scope of this invention should be defined by the following claims.

What is claimed is:

1. A patterning method, comprising:
sequentially forming a first mask layer, a second mask layer and a patterned photoresist layer on a target layer;
etching the second mask layer by using the patterned photoresist layer as a mask, so as to form a patterned second mask layer;
performing a trimming process to the patterned second mask layer;
etching the first mask layer by using the trimmed patterned second mask layer as a mask, so as to form a patterned first mask layer;
removing the patterned photoresist layer; and
etching the target layer by using the patterned first mask layer as a mask.

2. The patterning method of claim 1, wherein the target layer comprises polysilicon.

3. The patterning method of claim 1, wherein the first mask layer and the second mask layer comprise different materials.

4. The patterning method of claim 1, wherein the first mask layer comprises silicon nitride, and the second mask layer comprises silicon oxide.

5. The patterning method of claim 1, wherein the first mask layer comprises silicon oxide, and the second mask layer comprises silicon nitride.

6. The patterning method of claim 1, wherein the patterned photoresist layer has multiple layers.

7. The patterning method of claim 6, wherein the patterned photoresist layer comprises, from bottom to top, a 365 nm photoresist layer, a Si-containing hard-mask bottom anti-reflection coating (SHB) layer and a 193 nm photoresist layer.

8. The patterning method of claim 1, wherein the step of forming the patterned first mask layer and the step of forming the patterned second mask layer each comprise performing a dry etching process, in which reaction gases comprise CF₄, HBr, CHF₃, He or a combination thereof.

9. The patterning method of claim 1, wherein the step of forming the patterned second mask layer comprises using HBr gas, so as to prevent the patterned photoresist layer from collapsing.

10. The patterning method of claim 9, wherein a flow rate of HBr gas is about 100-150 sccm.

11. The patterning method of claim 1, wherein a time of the trimming process is about 40-60 seconds.

12. A patterning method, comprising:
sequentially forming a first mask layer, a second mask layer and a patterned photoresist layer on a target layer;
sequentially etching the second mask layer and the first mask layer by using the patterned photoresist layer as a mask, so as to form a patterned second mask layer and a patterned first mask layer;
performing a trimming process to the patterned second mask layer and the patterned first mask layer;
removing the patterned photoresist layer; and
etching the target layer by using the trimmed patterned first mask layer as a mask.

13. The patterning method of claim 12, wherein the target layer comprises polysilicon.

14. The patterning method of claim 12, wherein the first mask layer and the second mask layer comprise different materials.

15. The patterning method of claim 12, wherein the first mask layer comprises silicon nitride, and the second mask layer comprises silicon oxide.

16. The patterning method of claim 12, wherein the first mask layer comprises silicon oxide, and the second mask layer comprises silicon nitride.

17. The patterning method of claim 1, wherein the patterned photoresist layer has multiple layers.

18. The patterning method of claim 17, wherein the patterned photoresist layer comprises, from bottom to top, a 365 nm photoresist layer, a SHB layer and a 193 nm photoresist layer.

19. The patterning method of claim 12, wherein the step of forming the patterned second mask layer and the patterned first mask layer does not comprise using HBr gas.

20. The patterning method of claim 12, wherein a time of trimming process is about 50-70 seconds.
